(19) United States
(12) Patent Application Publication
(10) Pub. No.: US 2026/0318839 A1
(43) Pub. Date: Oct. 15, 2026

(54) AUTOMATED SENSITIVITY TUNER FOR DEFECT INSPECTION

(71) Applicant: KLA Corporation, Milpitas, CA (US)

(72) Inventors: Bradley Ries, San Jose, CA (US); Sayi Tummalapalli, San Ramon, CA (US)

(21) Appl. No.: 19/289,391

(22) Filed: Aug. 4, 2025

Related U.S. Application Data
(60) Provisional application No. 63/786,279, filed on Apr. 9, 2025.
(60) Provisional application No. 63/791,521, filed on Apr. 20, 2025.
(60) Provisional application No. 63/791,715, filed on Apr. 21, 2025.
(60) Provisional application No. 63/799,114, filed on May 2, 2025.
(60) Provisional application No. 63/799,104, filed on May 2, 2025.
(60) Provisional application No. 63/799,067, filed on May 2, 2025.

(51) Int. Cl. G01N 21/88

(52) U.S. Cl. CPC G01N 21/8806; G01N 21/8851; G01N 2021/8822; G01N 2021/8858; G01N 2021/8864; G01N 2021/8877; G01N 2201/1296

(57) ABSTRACT

An inspection system may include one or more controllers with one or more processors configured to execute program instructions. The system can receive inspection data for one or more samples from an inspection tool. The processors may identify values of detection parameters of a detection model that can provide selected detection rates of probable defects of interest and probable nuisances. The detection model may identify potential defects on the samples by comparing the inspection data to reference data and applying thresholds associated with the detection parameters. The system can generate an inspection recipe that may include at least the values of the detection parameters for the detection model. The system may identify defects on one or more additional samples based on the inspection recipe.

### CROSS-REFERENCE TO RELATED APPLICATIONS

The present application claims the benefit under 35 U.S.C. § 119(e) of U.S. Provisional Application Ser. Nos. 63/786,279 filed on Apr. 9, 2025; 63/791,521 filed on Apr. 20, 2025; 63/791,715 filed on Apr. 21, 2025; 63/799,114 filed on May 2, 2025; 63/799,104 filed on May 2, 2025; and 63/799,067 filed on May 2, 2025; all of which are incorporated herein by reference in their entireties.

### TECHNICAL FIELD

The present disclosure relates to semiconductor inspection systems, and more particularly to automated sensitivity tuning for defect detection in semiconductor wafer inspection.

### BACKGROUND

Semiconductor manufacturing processes continue to advance, leading to increasingly complex and densely packed integrated circuits. As feature sizes shrink and wafer sizes grow, detecting defects during the manufacturing process becomes more challenging. Inspection systems play a crucial role in identifying potential issues that could impact device performance or yield. However, distinguishing actual defects from benign variations or noise in inspection data remains an ongoing challenge.

Tuning inspection system sensitivity involves balancing the detection of true defects against false positives. This process traditionally requires significant time and expertise to optimize detection parameters for each specific manufacturing layer and process. There is therefore a need to develop systems and methods that address the above deficiencies.

### SUMMARY

In some embodiments, an inspection system is provided. The inspection system may include one or more controllers including one or more processors configured to execute program instructions causing the one or more processors to receive inspection data for one or more samples from an inspection tool. The one or more processors may select values of detection parameters of a detection model by generating a receiver operating characteristic (ROC) dataset relating identified probable defects of interest to a total defect event count for different operating points of the detection model. The detection model may identify potential defect events on the one or more samples by comparing the inspection data to reference data and applying thresholds associated with the detection parameters. The one or more processors may select one of the operating points of the detection model and provide the values of the detection parameters associated with the selected one of the operating points. The one or more processors may generate an inspection recipe that includes at least the values of the detection parameters for the detection model. The one or more processors may identify defects on one or more additional samples based on the inspection recipe.

In some embodiments, the selected one of the operating points may provide a desired detection rate of probable defects of interest relative to a desired total defect count.

In some embodiments, selecting one of the operating points of the detection model may include providing at least a portion of the ROC dataset to a user and receiving the selected one of the operating points from the user.

In some embodiments, selecting one of the operating points of the detection model may include selecting one of the operating points of the detection model based on one or more performance criteria.

In some embodiments, the one or more performance criteria may include at least one of a minimum detection rate of the probable defects, a maximum total defect count, or a ratio of the detection rate of the probable defects to the total defect count.

In some embodiments, generating the ROC dataset relating the identified probable defects of interest to the total defect event count for the different operating points of the detection model may include generating the ROC dataset relating identified probable defects of interest to the total defect event count for different operating points of the detection model using an unsupervised model.

In some embodiments, the unsupervised model may classify the potential defect events in the inspection data as the probable defects of interest or probable nuisances based on a multi-dimensional clustering analysis in a multi-dimensional parameter space including at least some of the detection parameters.

In some embodiments, the unsupervised model may classify the defect events in the inspection data as the probable defects of interest or the probable nuisances based on the multi-dimensional clustering analysis in the multi-dimensional parameter space including at least some of the detection parameters by generating one or more attribute plots with the defect events from a hot scan associated with the inspection data. Axes of a particular one of the one or more attribute plots may include two or more of the detection parameters. The unsupervised model may assign an outlier ranking to the defect events based on the one or more attribute plots and classify the defect events in the inspection data as the probable defects of interest or the probable nuisances based on the outlier ranking.

In some embodiments, the outlier ranking may be associated with a defect density in the one or more attribute plots.

In some embodiments, the outlier ranking for a particular defect event may be associated with one or more distances of the particular defect event from one or more clusters identified in the one or more attribute plots.

In some embodiments, the one or more attribute plots may include two or more attribute plots associated with different combinations of at least some of the detection parameters.

In some embodiments, the one or more attribute plots may include a single attribute plot.

In some embodiments, the single attribute plot may include all of the detection parameters.

In some embodiments, the single attribute plot may include a subset of the detection parameters.

In some embodiments, generating the ROC dataset relating the identified probable defects of interest to the total defect event count for the different operating points of the detection model may include generating the ROC dataset to relate the identified probable defects of interest to the total defect event count for the different operating points of the detection model using a supervised model.

In some embodiments, the supervised model may be trained with training inspection data associated with known classifications.

In some embodiments, an inspection system is provided. The inspection system may include an inspection tool configured to generate inspection data and one or more controllers including one or more processors configured to execute program instructions causing the one or more processors to receive the inspection data for one or more samples from the inspection tool. The one or more processors may select values of detection parameters of a detection model by generating a ROC dataset relating identified probable defects of interest to a total defect event count for different operating points of the detection model. The detection model may identify potential defect events on the one or more samples by comparing the inspection data to reference data and applying thresholds associated with the detection parameters. The one or more processors may select one of the operating points of the detection model and provide the values of the detection parameters associated with the selected one of the operating points. The one or more processors may generate an inspection recipe that includes at least the values of the detection parameters for the detection model and identify defects on one or more additional samples based on the inspection recipe.

In some embodiments, the inspection tool may include an optical inspection tool.

In some embodiments, the inspection tool may include a darkfield optical inspection tool.

In some embodiments, the selected one of the operating points may provide a desired detection rate of probable defects of interest relative to a desired total defect count.

In some embodiments, generating the ROC dataset relating the identified probable defects of interest to the total defect event count for the different operating points of the detection model may include generating the ROC dataset to relate the identified probable defects of interest to the total defect event count for the different operating points of the detection model using an unsupervised model.

In some embodiments, the unsupervised model may classify the potential defect events in the inspection data as the probable defects of interest or probable nuisances based on a multi-dimensional clustering analysis in a multi-dimensional parameter space including at least some of the detection parameters.

In some embodiments, the unsupervised model may classify the potential defect events in the inspection data as the probable defects of interest or the probable nuisances based on the multi-dimensional clustering analysis in the multi-dimensional parameter space including at least some of the detection parameters by generating one or more attribute plots with defect events from a hot scan associated with the inspection data. Axes of a particular one of the one or more attribute plots may include two or more of the detection parameters. The unsupervised model may assign an outlier ranking to the defect events based on the one or more attribute plots and classify the defect events in the inspection data as the probable defects of interest or the probable nuisances based on the outlier ranking.

In some embodiments, generating the ROC dataset relating the identified probable defects of interest to the total defect event count for the different operating points of the detection model may include generating the ROC dataset to relate the identified probable defects of interest to the total defect event count for the different operating points of the detection model using a supervised model.

In some embodiments, an inspection method is provided. The inspection method may include generating inspection data on one or more samples and selecting values of detection parameters of a detection model by generating a ROC dataset relating identified probable defects of interest to a total defect event count for different operating points of the detection model. The detection model may identify potential defect events on the one or more samples by comparing the inspection data to reference data and applying thresholds associated with the detection parameters. The method may include selecting one of the operating points of the detection model and providing the values of the detection parameters associated with the selected one of the operating points. The method may include generating an inspection recipe that includes at least the values of the detection parameters for the detection model and identifying defects on one or more additional samples based on the inspection recipe.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF FIGURES

The numerous advantages of the disclosure may be better understood by those skilled in the art by reference to the accompanying figures.

FIG. 1A illustrates a block diagram of an inspection system, in accordance with one or more embodiments of the present disclosure.

FIG. 1B illustrates a block diagram of an inspection sub-system, in accordance with one or more embodiments of the present disclosure.

FIG. 2 illustrates a flowchart of a method for generating and using an inspection recipe based on automated sensitivity tuning, in accordance with one or more embodiments of the present disclosure.

FIG. 3 illustrates a receiver operating characteristics (ROC) curve with defect maps associated with selected operating points, in accordance with one or more embodiments of the present disclosure.

FIG. 4 illustrates an attribute plot depicting inspection data in a two-dimensional attribute space based on two detection parameters of a detection algorithm, in accordance with one or more embodiments of the present disclosure.

FIG. 5 illustrates a bar graph comparing defect detection results for multiple parameter tuning techniques, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods providing automated sensitivity tuning (AST) of a detection model, which may be, but is not required to be, utilized when generating an inspection recipe.

An inspection recipe may include one or more models designed to identify and/or classify defects on a sample based on inspection data from an inspection tool (e.g., a tool suitable for high-volume manufacturing (HVM) such as, but not limited to, an optical inspection tool). In many cases, it may be desirable to train or otherwise develop these models based at least in part on ground truth data generated through reviewing defects using a review tool (e.g., a scanning electron microscope (SEM), or the like). However, when developing an inspection recipe, a user may have limited information on relevant data including the specific defect types present, locations of these defects, or parameter values needed to tune the models to distinguish between defects of interest (DOIs) and nuisances. Further, it may generally be desirable to limit or minimize the usage of inspection and/or review tools when developing an inspection recipe to save time and free such tools for other operations.

In embodiments, a detection model suitable for classifying inspection data associated with a sample into different classes (e.g., probable DOI, probable nuisance, or the like) may be utilized when generating an inspection recipe and/or implementing an inspection recipe. A detection model may identify and/or classify defects by comparing inspection data to reference data (e.g., control data) and analyzing the result. For example, the detection model may apply various thresholds or analysis steps to determine whether any particular differences between the inspection data and the reference data should be classified as a probable DOI and/or a probable nuisance. In some cases, the detection model further classifies inspection defect events (e.g., differences between the inspection data and reference data) into specific classes of DOIs and/or nuisances. In embodiments, the detection model may include various detection parameters, where the values of the detection parameters impact, define, and/or control the thresholds used to identify and/or classify the defects. In this way, the ability of the detection model to accurately distinguish between probable DOIs, probable nuisances, or sub-classes for identified objects on any particular samples may depend on the particular values of the detection parameters.

It is contemplated herein that a detection model may contain multiple (e.g., in some cases greater than 10) detection parameters that may have interrelated impacts on the detection thresholds and thus interrelated impacts on the ability to distinguish between probable DOIs, probable nuisances, or sub-classes thereof. It is further contemplated herein that inspection recipes that incorporate such detection models typically tune the detection parameters for a particular application manually based on a series of iterative inspection scans (e.g., with an inspection system such as, but not limited to, an optical inspection system) and review scans (e.g., with a review tool such as, but not limited to, a scanning electron microscope (SEM)). However, this manual approach typically requires many hours of work by a skilled application engineer as well as iterative operation of inspection and/or review tools.

In embodiments, AST may enable efficient determination of detection parameters that produce desired (e.g., selected) detection rates of probable DOIs and probable nuisances based on a single hot scan of one or more samples with an inspection system. The AST may implement any type of machine learning approach to classify defect events (e.g., as probable defects or probable nuisances) such as, but not limited to, supervised learning, unsupervised learning, semi-supervised learning, reinforcement learning, or any combination of learning approaches. For example, AST may employ supervised learning in which the system is trained on labeled data sets containing known defects of interest (DOIs) and nuisance detections. This supervised method may allow the AST to learn from pre-classified examples and fine-tune its detection criteria accordingly. As another example, the AST may implement unsupervised learning that does not require pre-labeled training data. In unsupervised AST, the system may analyze patterns and distributions in the inspection data to identify potential outliers or anomalies that are likely to represent true defects. This approach may be particularly useful when ground truth data is limited or unavailable. Both supervised and unsupervised AST methods may significantly reduce the time and expertise required for sensitivity tuning compared to manual approaches, potentially improving the overall efficiency and accuracy of semiconductor inspection processes.

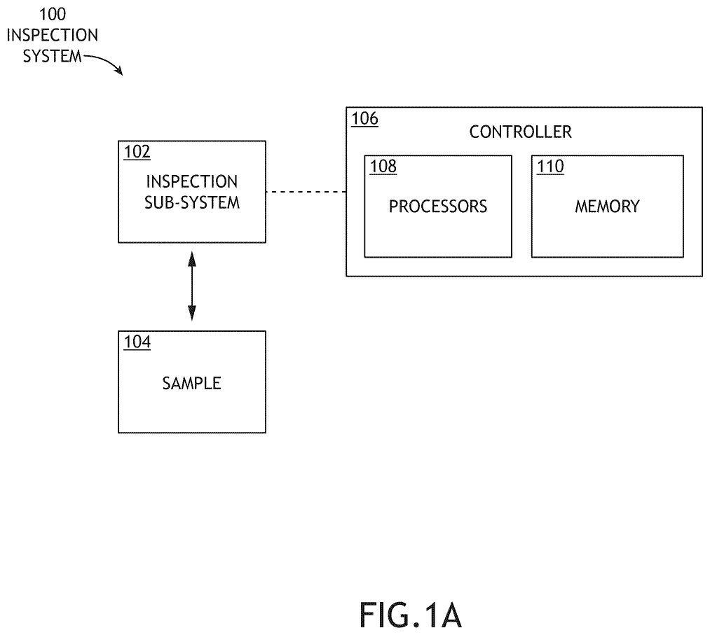

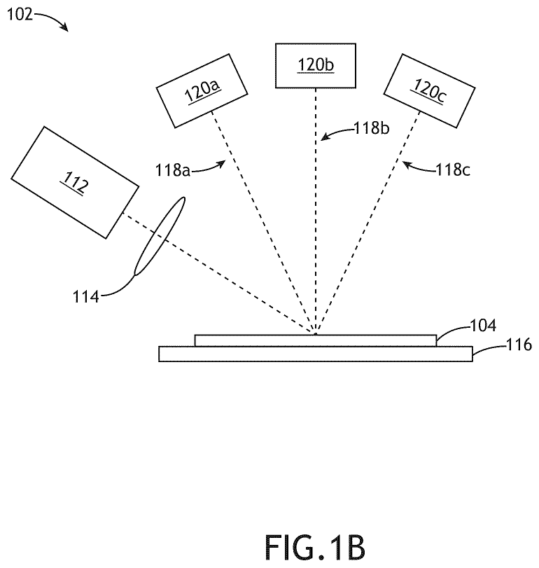

Referring now to FIGS. 1A-5, systems and methods providing automated sensitivity tuning of detection parameters of a detection model are described, in accordance with one or more embodiments of the present disclosure.

FIG. 1A illustrates a block diagram of an inspection system 100, in accordance with some embodiments of the present disclosure.

In embodiments, the inspection system 100 includes an inspection sub-system 102 to generate inspection data for one or more samples 104.

The sample 104 may include a substrate formed of a semiconductor or non-semiconductor material (e.g., a wafer, or the like). For example, a semiconductor or non-semiconductor material may include, but is not limited to, monocrystalline silicon, gallium arsenide, and indium phosphide. The sample 104 may further include one or more layers disposed on the substrate. For example, such layers may include, but are not limited to, a resist, a dielectric material, a conductive material, and/or a semiconductive material. Many different types of such layers are known in the art, and the term sample as used herein is intended to encompass a sample on which all types of such layers may be formed. One or more layers formed on a sample 104 may be patterned or unpatterned. For example, a sample may include a plurality of dies, each having repeatable patterned features. Formation and processing of such layers of material may ultimately result in completed devices. Many different types of devices may be formed on a sample, and the term sample as used herein is intended to encompass a sample on which any type of device known in the art is being fabricated.

The inspection sub-system 102 may generate inspection data of a sample 104 using any suitable technique. For example, the inspection sub-system 102 may be an imaging system that may generate one or more images of the sample 104 (e.g., darkfield images, brightfield images, or the like). In some cases, the inspection sub-system 102 may be an optical imaging system suitable for HVM that generates images. Non-limiting examples of an inspection system 100 include Voyager or Puma tools from KLA Corporation.

In embodiments, though not shown, the inspection system 100 includes a review tool to review selected locations on a sample 104. In some cases, the review tool may have a higher resolution but a slower throughput than the inspection sub-system 102. For example, the review tool may include, but is not limited to, a scanning electron microscope (SEM). In this way, review data from the review tool may operate as ground truth data that may be used to train defect detection models to identify defects from the HVM-suitable inspection sub-system 102.

The inspection system 100 may include one or more controllers 106 integrated within and/or communicatively coupled with the inspection sub-system 102 and/or the review tool. Any of the controllers of the inspection system 100 may include one or more processors 108 configured to execute program instructions maintained on memory 110, or a memory medium. In this regard, the one or more processors 108 of controller 106 may execute any of the various process steps described throughout the present disclosure.

The one or more processors of any controller may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors may include any device configured to execute algorithms and/or instructions (e.g., program instructions stored in memory). In some embodiments, the one or more processors may be embodied as a desktop computer, mainframe computer system, workstation, image computer, parallel processor, networked computer, or any other computer system configured to execute a program configured to operate or operate in conjunction with the inspection system 100, as described throughout the present disclosure.

The memory may include any storage medium known in the art suitable for storing program instructions executable by the associated one or more processors. For example, the memory may include a non-transitory memory medium. By way of another example, the memory may include, but is not limited to, a read-only memory (ROM), a random-access memory (RAM), a magnetic or optical memory device (e.g., disk), a magnetic tape, a solid-state drive and the like. It is further noted that memory may be housed in a common controller housing with the one or more processors. In some embodiments, the memory may be located remotely with respect to the physical location of the one or more processors and controller. For instance, the one or more processors of the controller may access a remote memory (e.g., server), accessible through a network (e.g., internet, intranet and the like).

In embodiments, the controller 106 may direct the operations of additional components of the inspection system 100 (e.g., via control signals) and/or perform operations on data received by the components of the inspection system 100. For example, the controller 106 may initiate a hot scan of a sample 104 using the inspection sub-system 102, process the resulting inspection data to identify potential defects, and apply initial detection parameters to classify the detected events. The controller 106 may then execute an automated sensitivity tuning algorithm to optimize the detection parameters, which may involve analyzing the distribution of detected events in a multi-dimensional parameter space. The controller 106 may also coordinate the transfer of selected events to a review tool, such as a SEM, and subsequently incorporate the review results into a machine learning model for improved defect classification. Additionally, the controller 106 may generate and store an inspection recipe based on the optimized parameters and classification model, which may be applied to future samples 104 for efficient defect detection.

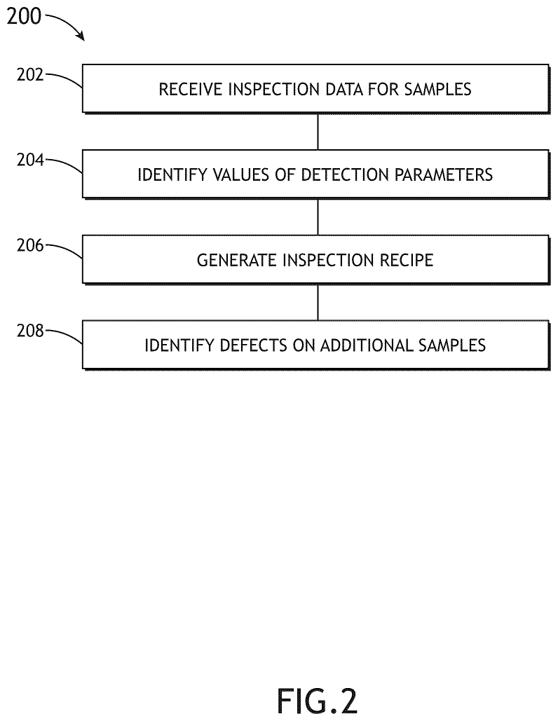

Referring now to FIGS. 2-5, techniques for automated sensitivity tuning are described, in accordance with one or more embodiments of the present disclosure.

FIG. 2 is a flow diagram illustrating steps performed in an inspection method 200. Applicant notes that the embodiments and enabling technologies described previously herein in the context of the inspection system 100 should be interpreted to extend to the method 200. For example, any of the steps of the method 200 may be performed directly or indirectly (e.g., by generating control signals to direct another component to perform a step) by any of the controllers of the inspection system 100 alone or in combination. It is further noted, however, that the method 200 is not limited to the architecture of the inspection system 100.

In embodiments, the method 200 includes a step 202 of receiving inspection data for one or more samples from an inspection tool. The inspection data may be received by the controller 106 of the inspection system 100. The controller 106 may receive the inspection data through a communication interface or data transfer mechanism connecting the inspection sub-system 102 to the controller 106. The processors 108 of the controller 106 may then store the received inspection data in the memory 110 for further processing and analysis in subsequent steps of the method 200.

The inspection data may have any format suitable for including information indicative of the presence or absence of one or more defects. For example, the inspection data may be in a format suitable for comparison with reference data known to be free of defects using a detection model.

In embodiments, a detection model may identify potential defects, referred to herein as defect events) on the one or more samples 104 by comparing the inspection data to reference data and applying thresholds associated with the detection parameters. As an illustration in the context of an image-based detection model, the detection model may compare pixel intensities or other image characteristics between corresponding regions of an inspection image (e.g., an image of a portion of a sample 104 being inspected) and a reference image (e.g., a real or simulated image of a corresponding portion of the sample 104 known to be free of defects). The detection model may then apply processing steps such as, but not limited to, filtering, clustering, or classification steps to distinguish probable DOIs from nuisance events, where the operation of these steps may be controlled by various detection parameters. For example, the detection parameters may define thresholds or other controls that determine whether variations between the inspection data and reference data are classified as potential defects.

In some cases, the inspection data received in step 202 may correspond to or may be used to generate a “hot scan” of the one or more samples 104. A hot scan may refer to an inspection process where the inspection sub-system 104 and/or the detection model are configured to capture a wide range of potential defects or anomalies that may be at or near a noise floor of the sample 104 and/or the inspection sub-system 104, including those that may later be classified as DOIs or nuisances. For example, the detection model may run with a default set of detection parameters that provide high sensitivity to a wide range of defects (e.g., low thresholds). For this reason, the hot scan may also be referred to as a default scan. This approach may provide a comprehensive dataset for subsequent analysis and parameter optimization steps in the method 200.

In some cases, though not explicitly shown in FIG. 2, the method 200 may also implement a neural network model, which may be referred to as a mother model, to perform an initial classification of defect events associated with the inspection data generated in step 202. In some cases, the neural network model may perform an initial classification of defect events associated with a hot scan or default scan.

The neural network model may assign probabilities or confidence scores for various defect categories. The detection model may classify the defect events into any number or type of categories. As an illustration, the neural network model may classify defect events in the hot scan into high-confidence DOIs, low-confidence DOIs, high-confidence nuisance events, and low-confidence nuisance events. As another illustration, the neural network model may classify defect events by defect type. However, these are merely illustrations and not limiting. The neural network model (e.g., the mother model) may classify defect events from the hot scan into any number or type of classes.

The neural network model may be trained using a diverse set of training data comprising historical inspection data from multiple layers and defect types. In this way, the neural network model may be generalized beyond the current layer of a sample 104 being inspected and/or the particular process used. This training data may include, but is not limited to, images of known DOIs and nuisances, along with associated metadata such as defect size, location, and classification. The model may utilize a deep learning architecture, such as a convolutional neural network (CNN), to extract relevant features from the input data and learn to distinguish between various DOIs and nuisances.

The method 200 may include a step 204 of identifying values of detection parameters for a detection model, where the detection model identifies and/or classifies defects based on the inspection data from step 202. This step 204 may be performed with an AST and/or may describe the operation of an AST. When performed with the inspection system 100, this step 204 may be implemented by the controller 106.

As described previously herein, a detection model may identify potential defects (e.g., defect events) by comparing the inspection data to reference data and applying thresholds associated with the detection parameters. In this way, the detection parameters may control the sensitivity of the detection model to certain types of defects.

It is contemplated herein that the defect detection parameters may have many interrelated effects such that determining suitable values for these parameters may be complex, tedious, and time consuming. For example, a detection model may have five, ten, or more detection parameters that may provide interrelated effects. As a result, the task of selecting suitable values of the detection parameters suitable for distinguishing probable DOIs from probable nuisances is a multi-dimensional selection problem (e.g., an n-dimensional selection problem for a detection model with n parameters that may be tuned).

When performed manually, this process typically requires multiple iterations of hot scans and/or review steps. In contrast, the AST may automate the process and may require little or no user interaction. In embodiments, an AST implements a machine learning technique to evaluate a parameter space (e.g., an n-dimensional parameters space) associated with the detection parameters for a selected detection model to determine values of the detection parameters that distinguish between probable DOIs and probable nuisance events.

In embodiments, the AST generates a receiver operating characteristic (ROC) dataset (e.g., curve) describing possible configurations (e.g., operating points) of the detection model. For example, an ROC curve may plot a retention rate of probable DOIs as a function of total number of defect events, where each point on the ROC corresponds to the operation of the detection model with different values of the detection parameters (and thus different operating thresholds) as determined by the AST. In this way, each point on the ROC (e.g., each operating point of the detection model) may be the result of an n-dimensional analysis of the detection parameter space (e.g., n detection parameters being tuned).

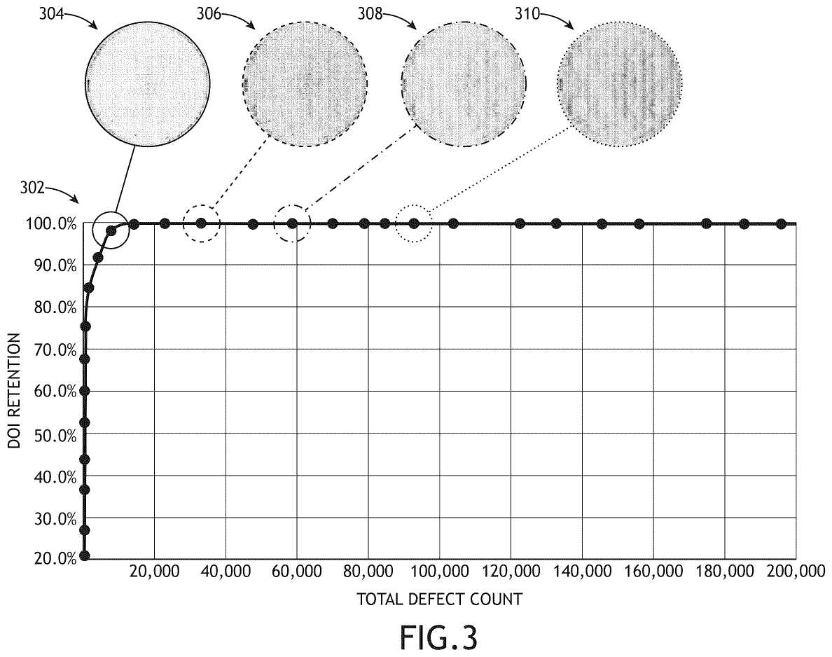

FIG. 3 illustrates a receiver operating characteristic (ROC) curve 302, in accordance with one or more embodiments of the present disclosure. In FIG. 3, the defect retention rate (e.g. a retention rate of probable DOIs) is plotted relative to total defect count (e.g., a total number of events identified by a detection model). It may be the case that a defect model may not perfectly distinguish probable DOIs from probable nuisances. Rather, a defect model may typically output defect events that include both probable DOIs as well as probable nuisances and, in some cases, may identify many more probable nuisances than probable DOIs. In most cases, increasing the total defect count from the defect model results in higher percentages of probable DOIs. Further, as shown in FIG. 3, the ROC curve may show a rapid increase in DOI retention rate followed by a more gradual increase until or approaching 100%. FIG. 3 further depicts insets associated with defect maps associated with selected operating points of the ROC curve 302. In particular, FIG. 3 depicts a first defect map 304, a second defect map 306, a third defect map 308, and a fourth defect map 310, each at increasing total defect counts as seen by the increasing density in the associated defect maps.

It is contemplated herein that generating an ROC curve may allow for the dynamic selection of a desired performance level of the detection model based on the requirements of any particular application. In particular, each point on the ROC curve represents a different balance between a number of total defect events (e.g., total defect count) and a number of probable DOIs captured by particular settings of the detection model.

In some applications, the step 204 may include presenting the ROC curve to a user (e.g., via a display device), receiving input from the user about a selected operating point, and providing the values of the detection parameters associated with the user-selected operating point. In some cases, the step 204 may include selecting an operating point according to one or more performance criteria such as, but not limited to, a minimum DOI detection rate, a maximum total defect count, or a ratio of the two. In this way, the inspection system 100 and/or a user may define an algorithm or a set of criteria to select the operating point in an automated way.

The AST may utilize any multiple parameter optimization technique known in the art to select values detection parameters that provide desired detection rates of probable DOIs and/or probable nuisances (e.g., that provide a selected point on an ROC curve). For example, the AST may perform a global optimization to identify values of the detection parameters that provide the desired detection rates. In some cases, to mitigate potential local minima or maxima, the AST may incorporate randomness. For example, the AST may occasionally select one or more detection parameters to change randomly, which may facilitate the discovery of potentially beneficial configurations that might otherwise be overlooked by a purely deterministic approach.

When generating the ROC curve, the AST relies on some classification of defect events into probable DOIs or probable nuisances. The AST may utilize any combination of machine learning techniques to classify defect events when generating an ROC curve and/or providing detection parameter values associated with a selected operating point including, but not limited to, supervised learning, unsupervised learning, semi-supervised learning, or reinforcement learning. As used herein, the term “machine learning technique” refers to a computational method that uses algorithms and statistical models to enable computer systems to improve their performance on a specific task through experience. In the context of the present disclosure, machine learning techniques may include supervised learning, unsupervised learning, or reinforcement learning approaches applied to analyze inspection data and optimize detection parameters. “Supervised learning” refers to a type of machine learning where the algorithm is trained on a labeled dataset, meaning the input data is paired with corresponding output labels. “Unsupervised learning” refers to a type of machine learning where the algorithm analyzes unlabeled data to find patterns or groupings without pre-existing output labels.

In embodiments, if ground truth data including inspection images of known DOIs and known nuisances is available, the AST may utilize a supervised machine learning technique that utilizes this ground truth data (e.g., as training data). This ground truth data may be derived from any source including, but not limited to, inspection and review of fabricated samples (e.g., with an inspection sub-system 102 and a review tool) or from historical datasets that may be associated with various processes or fabricated features. The AST may then identify the detection parameters that provide selected detection rates of probable DOIs and probable nuisances (e.g., associated with a selected operating point of an ROC curve) based on these supervised classifications.

In embodiments, the AST may use unsupervised techniques to distinguish probable DOIs from probable nuisance events without relying on ground truth data whether or not it is available. In the context of the present disclosure, unsupervised learning may involve the AST analyzing inspection data to identify potential defects of interest and nuisances based on inherent patterns in the data, without relying on pre-classified examples.

For example, the AST may perform a multi-dimensional analysis of the hot scan (e.g., including defect events from the detection algorithm with parameters selected to capture defects are or near a noise floor) in an attribute space corresponding to at least some of the detection parameters that are being tuned. As an illustration, the unsupervised AST may generate or consider one or more attribute plots of the hot scan defect events, where an attribute plot may describe the defect events as a function of two or more detection parameters of the detection model that are being tuned. Put another way, two or more detection parameters may be the axes of an attribute plot.

The AST may then utilize an outlier detection algorithm to identify potential outliers in the multi-dimensional attribute space. For example, the AST may utilize clustering algorithms such as, but not limited to, k-means or Gaussian mixture models to identify clusters in the multi-dimensional parameter space and identify outliers based on the clusters. It is contemplated herein that clusters of defect events may likely represent background data or nuisances not critical to operation of a fabricated device on the sample 104. In contrast, outliers or defect events that are relatively separated from the clusters may be more likely to be DOIs.

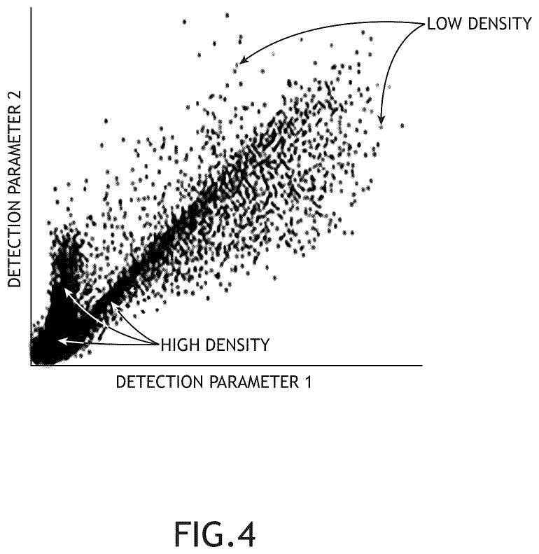

FIG. 4 illustrates a non-limiting example of a two-dimensional attribute plot, in accordance with one or more embodiments of the present disclosure. In FIG. 4, detection parameter 1 is plotted on the x-axis and detection parameter 2 is plotted on the y-axis, with each point representing a detected event from the inspection data. In this way, the attribute plot in FIG. 4 is a two-dimensional plot. However, an attribute plot may generally have any number of dimensions associated with any number of detection parameters. In some cases, an attribute plot includes n dimensions, where n is a number of the detection parameters being tuned.

As shown in FIG. 4, plotting defect events in a multi-dimensional space may reveal high-density clusters of defect events that may be more likely to be nuisances as well as reveal isolated or low-density regions of defect events that may be more likely to be DOIs.

In embodiments, the AST assigns an outlier ranking to each of the defect events in an attribute plot, which may operate as an unsupervised metric for ranking outlier events. The AST may then classify the defect events as probable defects of interest or probable nuisances based on the outlier rankings. As described above, these classifications may be used when performing multi-parameter optimization to select values of detection parameters when generating an ROC curve.

The outlier rankings may be based on any criteria. For example, the outlier rankings may be associated with defect density in one or more attribute plots, where defect events in relatively low-density regions of the plot may receive a higher outlier ranking than defect events in relatively high-density regions of the plot. As another example, the outlier rankings may be associated with one or more distances of particular defect events from one or more clusters identified in the attribute plots. In this case, defect events located relatively further from the clusters in the attribute space may be assigned higher outlier rankings than defect events located relatively closer to or within any of the clusters.

The unsupervised AST may utilize any number of attribute plots to analyze the inspection data. It is contemplated herein that certain combinations of detection parameters may provide more pronounced clusters than others and may thus be more suitable for distinguishing between at least certain types of probable DOIs and probable nuisances. Put another way, each attribute plot may provide a different perspective on the inspection data by focusing on different combinations of detection parameters.

In some cases, the AST may utilize a single attribute plot, which may include all of the detection parameters or a subset of the detection parameters. Alternatively, the attribute plots may comprise two or more attribute plots associated with different combinations of at least some of the detection parameters. In the case where two or more attribute plots are utilized, the outlier rankings and the associated classifications may be based on a combination of considerations (e.g., defect density, distance from clusters, or the like) from the two or more attribute plots.

It is to be understood that the descriptions of attribute plots herein merely refer to consideration of the associated multi-dimensional data and do not require the generation of a visual representation of the data. The systems and methods described may process and analyze the data in ways that correspond to the described visual representations, without actually creating or displaying such visualizations. In some cases, the described plots or graphs may serve as conceptual aids to understand the data analysis processes, while the actual implementation may involve purely numerical or algorithmic operations on the data without generating visual outputs. However, in other implementations, the system may generate and display visual representations as described, depending on the specific requirements and capabilities of the particular embodiment.

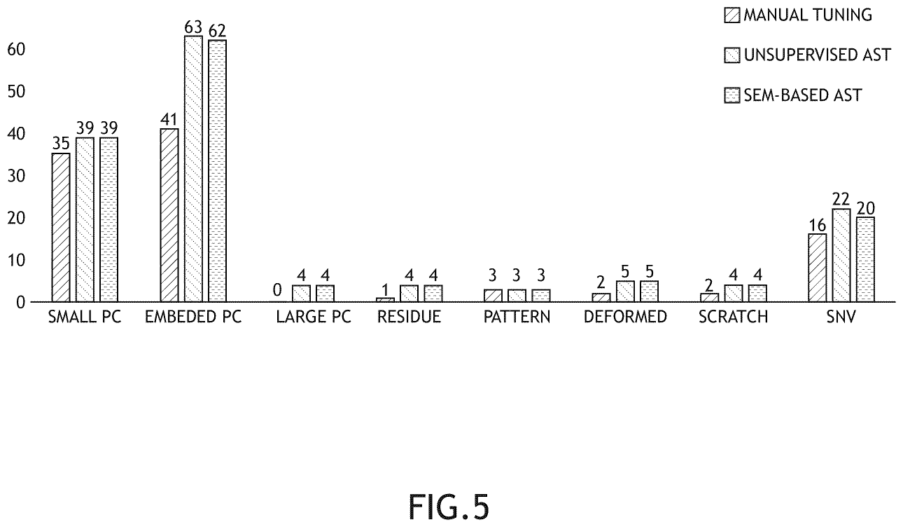

FIG. 5 illustrates a bar graph comparing defect detection results across different defect categories using a detection model having parameters tuned using different techniques (e.g., manually, with an unsupervised AST, and with a supervised AST), in accordance with one or more embodiments of the present disclosure. In particular, FIG. 5 shows capture rate ratios of seven different classes of DOIs (labeled Small PC, Embedded PC, Large PC, Residue, Pattern, Deformed, and Scratch) along with nuisances (SNV).

As shown in FIG. 5, the unsupervised AST configuration may provide roughly equivalent and sometimes superior performance than the supervised configuration. In this way, unsupervised AST, which does not require the generation of ground truth data, may provide efficient and automated selection of detection parameters to distinguish probable DOIs from probable nuisance events.

The method 200 may include a step 206 of generating an inspection recipe that may be used in a HVM environment. When performed with the inspection system 100, the step 206 may be implemented by the controller 106. In some cases, the processors 108 of the controller 106 may execute program instructions stored in the memory 110 to perform the step 206.

The inspection recipe generated in the step 206 may include at least the values of the detection parameters for the detection model. These values may be the ones identified in the step 204 through the automated sensitivity tuning process. In some cases, the inspection recipe may further include an additional classification model (e.g., a nuisance rejection model, a nuisance optimization model) and/or associated parameters. For example, it may be the case that the detection model tuned in step 204 may not have sufficient context to fully distinguish between DOIs and nuisances. In this case, the additional classification model may operate on the output of the detection model as well as additional information such as, but not limited to, information about die geometry (e.g., care areas, or the like), or a wafer map. The additional classification model may incorporate any machine learning or classification technique including, but not limited to, random forest classification. The inspection recipe may also include additional information such as, but not limited to, inspection tool settings, data processing algorithms, or classification rules.

The generation of the inspection recipe in the step 206 may represent a culmination of the automated sensitivity tuning process. By incorporating the optimized detection parameter values into the inspection recipe, the method 200 may enable efficient and consistent application of the tuned detection model to future inspections of samples 104. Further, the use of automated parameter tuning in step 204 may enable efficient generation of the inspection recipe using a single hot scan (e.g., generated by the inspection sub-system 102) and may be performed with a wide variety of users with a wide variety of skill levels.

In some cases, the inspection recipe generated in the step 206 may be stored in the memory 110 of the controller 106. The stored inspection recipe may be readily accessible for future use, allowing for quick setup and execution of inspection processes on the inspection sub-system 102. In some cases, the inspection recipe generated in the step 206 may be further refined or updated based on additional data or feedback from subsequent inspections. This may allow for continuous improvement of the inspection process over time.

Referring again to FIG. 2, the method 200 may include a step 208 of identifying defects on one or more additional samples based on the inspection recipe. In some cases, the processors 108 of the controller 106 may execute program instructions stored in the memory 110 to perform or direct the performance of the step 208.

The step 208 may involve configuring the inspection sub-system 102 or other HVM tools based on the inspection recipe generated in the step 206. This configuration may enable efficient identification and/or classification of defects in a HVM environment.

In some cases, the controller 106 may apply the detection model with the tuned detection parameters from the inspection recipe to inspection data from one or more additional samples 104. The detection model may compare the inspection data to reference data and apply thresholds associated with the detection parameters to identify potential defects on the one or more additional samples 104.

The step 208 may further involve applying any additional classification models included in the inspection recipe, if present. For example, the controller 106 may apply a nuisance rejection model or a nuisance optimization model to further refine the classification of detected events as probable DOIs or probable nuisances.

In some cases, the step 208 may generate output similar to the defect maps shown in FIG. 3, such as the first defect map 304, the second defect map 306, the third defect map 308, or the fourth defect map 310. The particular defect map generated may depend on the operating point selected for the detection model in the inspection recipe.

The step 208 may enable efficient and consistent defect detection across multiple samples 104 in a HVM environment. By utilizing the inspection recipe generated through the automated sensitivity tuning process, the method 200 may provide reliable defect detection without requiring manual tuning or adjustment for each new sample 104.

Referring generally to FIGS. 1A-5, the systems and methods disclosed herein may be used to generate an inspection recipe for any type of inspection sub-system 102 using review from any type of review tool, along with any associated inspection or review models.

FIG. 1B illustrates a block diagram of an inspection sub-system 102, in accordance with one or more embodiments of the present disclosure. For example, the inspection sub-system 102 may be a non-limiting illustration of a darkfield optical sub-system suitable for implementing the step 202.

In embodiments, the inspection sub-system 102 includes an illumination source 112 configured to generate an illumination beam. The illumination source 112 may include any type of illumination source known in the art suitable for generating an optical illumination beam. The illumination beam may have any spectrum such as, but not limited to, extreme ultraviolet (EUV) wavelengths, ultraviolet (UV) wavelengths, visible wavelengths, or infrared (IR) wavelengths. Further, the illumination source 112 may be a broadband source, a narrowband source, and/or a tunable source.

In embodiments, the illumination source 112 includes a broadband plasma (BBP) illumination. In this configuration, the illumination beam may include radiation emitted by a plasma. For example, a BBP illumination source 112 may include, but is not required to include, one or more pump sources (e.g., one or more lasers) configured to focus into the volume of a gas, causing energy to be absorbed by the gas in order to generate or sustain a plasma suitable for emitting radiation. Further, at least a portion of the plasma radiation may be utilized as the illumination beam.

In embodiments, the illumination source 112 may include one or more lasers. For instance, the illumination source 112 may include any laser system known in the art capable of emitting radiation in the infrared, visible, or ultraviolet portions of the electromagnetic spectrum.

The illumination source 112 may further produce an illumination beam having any temporal profile. For example, the illumination source 112 may produce continuous-wave (CW) illumination beam, pulsed illumination beam, or modulated illumination beam. Additionally, the illumination beam may be delivered from the illumination source 112 via free-space propagation or guided light (e.g., an optical fiber, a light pipe, or the like).

Although not shown, the inspection sub-system 102 may include various components to direct the illumination beam to the sample 104 such as, but not limited to, mirrors, lenses, diverters, filters (e.g., spatial and/or temporal filters), diffusers, homogenizers, apodizers, beamsplitters, or the like. Further, such components may be reflective elements or transmissive elements.

In embodiments, sample 104 is disposed on a stage assembly 116 to facilitate movement of sample 104. Stage assembly 116 may include any actuators known in the art including, but not limited to, an X-Y stage, an R-θ stage, a tip/tilt stage, or the like. Further, the stage assembly 116 is capable of adjusting the height of sample 104 during inspection or imaging to maintain focus on the sample 104.

In embodiments, inspection sub-system 102 includes one or more detection channels. The one or more detection channels may include one or more detectors configured to collect illumination scattered from the sample 104 and acquire images of the sample 104. For example, as shown in FIG. 1B, inspection sub-system 102 may include a first detection channel 118a including a first detector 120a, a second detection channel 118b including a second detector 120b, and a third detection channel 118c including a third detector 120c. In the configuration of FIG. 1B, the first detector 120a, the second detector 120b, and the third detector 120c are positioned to generate darkfield images based on light that is scattered and/or diffracted by the sample 104, where each detector generates an image with light from a different range of collection angles.

The one or more detectors (e.g., detectors 120a-120c) may include any type of sensor suitable for capturing scattered light from the sample 104 such as, but not limited to, complementary metal-oxide-semiconductor (CMOS) sensors, charge-coupled devices (CCDs), time delay integration (TDI) sensors, avalanche photodiodes (APDs), photomultiplier tubes (PMTs), or hybrid detectors combining multiple technologies.

Although not shown, the inspection sub-system 102 may include one or more optical elements 114 configured to collect illumination scattered from the sample 104 and direct the illumination to the one or more detectors. The one or more optical elements 114 may include any optical elements known in the art including, but not limited to, mirrors, lenses, diverters, filters (e.g., spatial and/or temporal filters), diffusers, homogenizers, apodizers, beamsplitters, or the like.

While FIG. 1B illustrates an inspection sub-system 102 including three detectors configured to acquire patch images along three scattering angles, this is not to be regarded as a limitation of the present disclosure, unless noted otherwise herein. In this regard, it is contemplated that inspection sub-system 102 may be arranged in any configuration including, but not limited to, a one-detection-channel configuration, a two-detection-channel configuration, a three-detection-channel configuration, a five-detection-channel configuration, and the like.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An inspection system comprising:
one or more controllers including one or more processors configured to execute program instructions causing the one or more processors to:
receive inspection data for one or more samples from an inspection tool;
select values of detection parameters of a detection model by:
generating a receiver operating characteristic (ROC) dataset relating identified probable defects of interest to a total defect event count for different operating points of the detection model, wherein the detection model identifies potential defect events on the one or more samples by comparing the inspection data to reference data and applying thresholds associated with the detection parameters;
selecting one of the operating points of the detection model; and
providing the values of the detection parameters associated with the selected one of the operating points;
generate an inspection recipe, wherein the inspection recipe includes at least the values of the detection parameters for the detection model; and
identify defects on one or more additional samples based on the inspection recipe.

2. The inspection system of claim 1, wherein the selected one of the operating points provides a desired detection rate of probable defects of interest relative to a desired total defect count.

3. The inspection system of claim 1, wherein selecting one of the operating points of the detection model comprises:
providing at least a portion of the ROC dataset to a user; and
receiving the selected one of the operating points from the user.

4. The inspection system of claim 1, wherein selecting one of the operating points of the detection model comprises:
selecting one of the operating points of the detection model based on one or more performance criteria.

5. The inspection system of claim 4, wherein the one or more performance criteria include at least one of a minimum detection rate of the probable defects, a maximum total defect count, or a ratio of the detection rate of the probable defects to the total defect count.

6. The inspection system of claim 1, wherein generating the receiver operating characteristic (ROC) dataset relating the identified probable defects of interest to the total defect event count for the different operating points of the detection model comprises:
generating the receiver operating characteristic (ROC) dataset relating identified probable defects of interest to the total defect event count for different operating points of the detection model using an unsupervised model.

7. The inspection system of claim 6, wherein the unsupervised model classifies the potential defect events in the inspection data as the probable defects of interest or probable nuisances based on a multi-dimensional clustering analysis in a multi-dimensional parameter space including at least some of the detection parameters.

8. The inspection system of claim 7, wherein the unsupervised model classifies the defect events in the inspection data as the probable defects of interest or the probable nuisances based on the multi-dimensional clustering analysis in the multi-dimensional parameter space including at least some of the detection parameters by:
generating one or more attribute plots with the defect events from a hot scan associated with the inspection data, wherein axes of a particular one of the one or more attribute plots include two or more of the detection parameters;
assigning an outlier ranking to the defect events based on the one or more attribute plots; and
classifying the defect events in the inspection data as the probable defects of interest or the probable nuisances based on the outlier ranking.

9. The inspection system of claim 8, wherein the outlier ranking is associated with a defect density in the one or more attribute plots.

10. The inspection system of claim 8, wherein the outlier ranking for a particular defect event is associated with one or more distances of the particular defect event from one or more clusters identified in the one or more attribute plots.

11. The inspection system of claim 8, wherein the one or more attribute plots comprise a two or more attribute plots associated with different combinations of at least some of the detection parameters.

12. The inspection system of claim 8, wherein the one or more attribute plots comprise a single attribute plot.

13. The inspection system of claim 12, wherein the single attribute plot includes all of the detection parameters.

14. The inspection system of claim 12, wherein the single attribute plot includes a subset of the detection parameters.

15. The inspection system of claim 1, wherein generating the receiver operating characteristic (ROC) dataset relating the identified probable defects of interest to the total defect event count for the different operating points of the detection model comprises:
generating the receiver operating characteristic (ROC) dataset to relate the identified probable defects of interest to the total defect event count for the different operating points of the detection model using a supervised model.

16. The inspection system of claim 15, wherein the supervised model is trained with training inspection data associated with known classifications.

17. An inspection system comprising:
an inspection tool configured to generate inspection data; and
one or more controllers including one or more processors configured to execute program instructions causing the one or more processors to:
receive the inspection data for one or more samples from the inspection tool;
select values of detection parameters of a detection model by:
generating a receiver operating characteristic (ROC) dataset relating identified probable defects of interest to a total defect event count for different operating points of the detection model, wherein the detection model identifies potential defect events on the one or more samples by comparing the inspection data to reference data and applying thresholds associated with the detection parameters;
selecting one of the operating points of the detection model; and
providing the values of the detection parameters associated with the selected one of the operating points;
generate an inspection recipe, wherein the inspection recipe includes at least the values of the detection parameters for the detection model; and
identifying defects on one or more additional samples based on the inspection recipe.

18. The inspection system of claim 17, wherein the inspection tool comprises:
an optical inspection tool.

19. The inspection system of claim 18, wherein the inspection tool comprises:
a darkfield optical inspection tool.

20. The inspection system of claim 17, wherein the selected one of the operating points provides a desired detection rate of probable defects of interest relative to a desired total defect count.

21. The inspection system of claim 17, wherein generating the receiver operating characteristic (ROC) dataset relating the identified probable defects of interest to the total defect event count for the different operating points of the detection model comprises:
generating the receiver operating characteristic (ROC) dataset to relate the identified probable defects of interest to the total defect event count for the different operating points of the detection model using an unsupervised model.

22. The inspection system of claim 21, wherein the unsupervised model classifies the potential defect events in the inspection data as the probable defects of interest or probable nuisances based on a multi-dimensional clustering analysis in a multi-dimensional parameter space including at least some of the detection parameters.

23. The inspection system of claim 22, wherein the unsupervised model classifies the potential defect events in the inspection data as the probable defects of interest or the probable nuisances based on the multi-dimensional clustering analysis in the multi-dimensional parameter space including at least some of the detection parameters by:
generating one or more attribute plots with defect events from a hot scan associated with the inspection data, wherein axes of a particular one of the one or more attribute plots include two or more of the detection parameters;
assigning an outlier ranking to the defect events based on the one or more attribute plots; and
classifying the defect events in the inspection data as the probable defects of interest or the probable nuisances based on the outlier ranking.

24. The inspection system of claim 17, wherein generating the receiver operating characteristic (ROC) dataset relating the identified probable defects of interest to the total defect event count for the different operating points of the detection model comprises:
generating the receiver operating characteristic (ROC) dataset to relate the identified probable defects of interest to the total defect event count for the different operating points of the detection model using a supervised model.

25. An inspection method comprising:
generating inspection data on one or more samples;
selecting values of detection parameters of a detection model by:
generating a receiver operating characteristic (ROC) dataset relating identified probable defects of interest to a total defect event count for different operating points of the detection model, wherein the detection model identifies potential defect events on the one or more samples by comparing the inspection data to reference data and applying thresholds associated with the detection parameters;
selecting one of the operating points of the detection model; and
providing the values of the detection parameters associated with the selected one of the operating points;
generating an inspection recipe, wherein the inspection recipe includes at least the values of the detection parameters for the detection model; and
identifying defects on one or more additional samples based on the inspection recipe.
